(19) United States
(12) Patent Application Publication
(10) Pub. No.: US 2026/0047456 A1
(43) Pub. Date: Feb. 12, 2026

(54) THREE-DIMENSIONAL PACKAGING DEVICES

(71) Applicant: Qorvo US, Inc., Greensboro, NC (US)

(72) Inventors: Tarak A. Railkar, Carrollton, TX (US); Jeffrey N. Miller, Allen, TX (US); Salvatore Finocchiaro, Dallas, TX (US); Bror Peterson, Fairview, TX (US)

(21) Appl. No.: 19/229,105

(22) Filed: Jun. 5, 2025

Related U.S. Application Data
(60) Provisional application No. 63/679,883, filed on Aug. 6, 2024.

(51) Int. Cl. H01L 23/538; H01L 23/34

(52) U.S. Cl. CPC H01L 23/5384; H01L 23/34

(57) ABSTRACT

A three-dimensional (3D) packaging device is provided. The 3D packaging device includes an interposer substrate, and a plurality of connection structures in the interposer substrate. The plurality of connection structures are configured to transmit at least one of an electrical signal, heat, fluid, or an optical signal.

### CROSS-REFERENCE TO RELATED APPLICATIONS

The present application claims the benefit of U.S. Provisional App. No. 63/679,883, entitled “THREE-DIMENSIONAL PACKAGING DEVICES” and filed on Aug. 6, 2024, which is hereby incorporated by reference in its entirety.

### FIELD OF THE INVENTION

This disclosure relates to radio frequency (RF) packaging technologies. In particular, this disclosure relates to three-dimensional (3D) packaging devices.

### BACKGROUND

Radio frequency (RF) technology forms the backbone of modern telecommunications, wireless networking, and countless electronic devices. At its core, RF technology involves the generation, transmission, and reception of radio waves across a spectrum of frequencies, enabling communication over short and long distances without the need for physical wires. The functionalities of different modules of a RF device are implemented by numerous dies with various different RF components. The dies are assembled or integrated to provide a variety of different functions. However, in existing RF packages, it often takes up a lot of space to integrate dies of various kinds. Also, heat dissipation in existing RF packages can be challenging due to higher integration level of dies.

Therefore, there is a need to improve the integration level as well as thermal management in RF packages.

### SUMMARY

Aspects of the disclosure include a 3D packaging device. The 3D packaging device includes an interposer substrate, and a plurality of connection structures in the interposer substrate. The plurality of connection structures are configured to transmit at least one of an electrical signal, heat, fluid, or an optical signal.

In some embodiments, the plurality of connection structures include a first via structure extending from a first surface of the interposer substrate to a second surface of the interposer substrate for transmitting a respective electrical signal.

In some embodiments, the first via structure includes a metal via.

In some embodiments, the first via structure includes a plurality of sub-vias cascaded from the first surface of the interposer substrate to the second surface of the interposer substrate. Each of the sub-vias is electrically coupled to another one of the sub-vias with a metal layer.

In some embodiments, the first surface of the interposer substrate includes a first metal layer and the second surface of the interposer substrate includes a second metal layer. The first metal layer and the second metal layer are separated by air.

In some embodiments, the plurality of connection structures include a second via structure extending from between a first surface of the interposer substrate and a second surface of the interposer substrate to one of the first surface or the second surface. The second via structure is configured to transmit a respective electrical signal.

In some embodiments, the second via structure includes another metal layer extending from between the first surface of the interposer substrate and the second surface of the interposer substrate to the one of the first surface or the second surface, and a metal layer between the first surface of the interposer substrate and the second surface of the interposer substrate, and in contact with the other metal layer.

In some embodiments, the plurality of connection structures include a heat spreader structure extending a first surface of the interposer substrate to a second surface of the interposer substrate for transferring the heat flow.

In some embodiments, the heat spreader structure includes a material with a thermal conductivity of equal to or greater than 1 W/(m·K).

In some embodiments, the plurality of connection structures includes a channel structure extending from a first surface of the interposer substrate to a second surface of the interposer substrate for transmitting the fluid.

In some embodiments, the channel structure includes mechanisms for fluidic transport.

In some embodiments, the plurality of connection structures includes an optical fiber for transmitting the optical signal.

In some embodiments, the interposer substrate includes one or more layers of metal, fabric, paper, plastic, or resin.

In some embodiments, the 3D packaging device further includes a heat sink structure on a perimeter of a first surface or a second surface of the interposer substrate, wherein the heat sink structure including a metal.

In some embodiments, the heat sink structure forms a frame circumventing a perimeter of the interposer substrate.

In some embodiments, the interposer substrate includes an opening, the opening having a surface disposed between a first surface and a second surface of the interposer substrate.

In some embodiments, the 3D packaging device further includes a die disposed in the opening.

In some embodiments, the 3D packaging device further includes a plurality of openings arranged on a perimeter of the interposer substrate, the openings configured to be filled with fluid or air.

In some embodiments, the 3D packaging device further includes a plurality of dies disposed on a first surface of the interposer substrate or a second surface of the interposer substrate through the plurality of connection structures.

In some embodiments, the plurality of dies includes at least a beamformer device, a radio frequency (RF) transceiver, RF linear noise amplification (LNA) device, a power amplifier (PA) device, or a stacked heterogeneous device of LNA and PA.

In some embodiments, the 3D packaging device further includes a second interposer substrate and a plurality of second connection structures in the second interposer substrate. The second interposer substrate is coupled with the interposer on the first surface or the second surface of the interposer substrate through the plurality of connection structures and the plurality of second connection structures. The plurality of connection structures and the plurality of second connection structures are coupled through one or more of a soldering structure, epoxy, metal, or a micro-channel structure.

In some embodiments, the interposer substrate has one of a rectangular shape, a triangular shape, a hollow shape, an “L”shape, a cross shape, or an irregular shape.

In some embodiments, the 3D packaging device further includes a die embedded in the interposer substrate such that the die is located between a first surface and a second surface of the interposer substrate.

### BRIEF DESCRIPTION OF THE DRAWINGS

FIGS. 1A and 1B each illustrate a system including a three-dimensional (3D) packaging device integrated with various other structures.

FIGS. 2A-2G each illustrates a respective 3D packaging device, according to embodiments of the present disclosure.

FIG. 3 illustrates different topographic shapes of a 3D packaging device, according to embodiments of the present disclosure.

FIGS. 4A-4E illustrate cross-sectional views of different 3D packaging devices, according to embodiments of the present disclosure.

FIGS. 5A and 5B each illustrates a 3D packaging device coupled with other structures, according to embodiments of the present disclosure.

FIG. 6 illustrates a cross-sectional view of an exemplary 3D packaging device coupled with other structures, according to embodiments of the present disclosure.

### DETAILED DESCRIPTION

The following detailed description is illustrative in nature and is not intended to limit the scope, applicability, or configuration of inventive embodiments disclosed herein in any way. Rather, the following description provides practical examples, and those skilled in the art will recognize that some of the examples may have suitable alternatives. Embodiments will hereinafter be described in conjunction with the appended drawings, which are not to scale (unless so stated), wherein like numerals/letters denote like elements. However, it will be understood that the use of a number to refer to a component in a given drawing is not intended to limit the component in another drawing labeled with the same number. In addition, the use of different numbers to refer to components in different drawings is not intended to indicate that the different numbered components cannot be the same or similar to other numbered components. Examples of constructions, materials, dimensions and fabrication processes are provided for select elements and all other elements employ that which is known by those skilled in the art.

As used herein, the term “about” refers to a given amount of value that may vary based on the particular technology node associated with the semiconductor device. Based on a particular technology node, the term “about” can refer to a given amount of value that varies, for example, within 10-30% of the value (e.g., ±10%, ±20%, or ±20% of that value, or ±30%).

Reference will now be made in greater detail to various embodiments of the subject matter of the present disclosure, some embodiments of which are illustrated in the accompanying drawings.

As used herein, the term “coupled to” or the like refers to two objects being connected to each other in some way. The coupling between the two objects can include any suitable connection such as electrical, mechanical, thermal, optical, etc. In various embodiments, the term “coupled to” is interchangeable with the term “connected to”.

Current and emerging RF, mixed-signal and even photonic applications often require a significant amount of module-level heterogeneous integration. These modules require a high density of on-module RF or electrical interconnects for their performance. Additionally, such interconnects often need to double up as conduits for heat removal. The present disclosure provides an approach to realize the aforementioned requirements through the design, fabrication and integration of a 3D packaging device, e.g., a multi-functional fabric (or Z-fabric) that also supports fluidic flow for enhanced thermal management.

Embodiments of the present disclosure provide a 3D packaging device configured to integrate various different types of dies, such as dies with RF functions, optical functions, thermal management functions, electrical functions, etc. The 3D packaging device may integrate dies in the vertical direction (e.g., z-direction), and optimize the heat management amongst dies with its ability to transfer heat vertically. Specifically, the 3D packaging device is a multi-functional layer of connection structures that can be customized for the intended application and is then integrated into microelectronic modules. For example, the 3D packaging device can include an interposer substrate (e.g., a laminate substrate) with a plurality of connection structures in the interposer substrate. In some embodiments, the 3D packaging device can be customized to include multiple electrical interconnects in the z-direction, such as plated vias that connect DC, RF or other electrical signals across its two surfaces. Such vias can be tailored for their size and shape, depending on the requirements of the application. In some embodiments, these vias can be selectively filled by plating or by a suitable thermally conductive material and be used as a path for heat removal. In some embodiments, the vias can be tailored to handle fluidic transport, for example, cooling fluids for advanced thermal management at a modular level. The 3D packaging device not only supports but enables high density of heterogeneous integration at a modular as well as at a sub-system level with a multi-functional purpose.

In some embodiments, the 3D packaging device is versatile, and supports features such as fine pitch matrix for transmission of electrical signals across its surfaces, thermal transport/heat removal path across its surfaces through thermal vias, and fluidic (e.g. cooling fluids) exchange across its surfaces. The 3D packaging device may also include openings (e.g., cut-out areas) that enables dies to be embedded. The 3D packaging device may be configured to include a Faraday cage, using strategically sized and placed vias, together with ground planes on the two sides of the 3D packaging device. In some embodiments, one or more dies can be incorporated into the 3D packaging devices. In some embodiments, the 3D packaging device is fabricated as an independent, customized layer and then integrated in the package being fabricated. The 3D packaging device may include one or more interconnect layers having various interconnects for electrical, mechanical, thermal, optical, and RF connection structures for coupling other parts in the package. This feature allows for flexibility in the manufacturing processes and can enhance the yields of complex 3D packaging device by integrating “known good layer” into the fabrication.

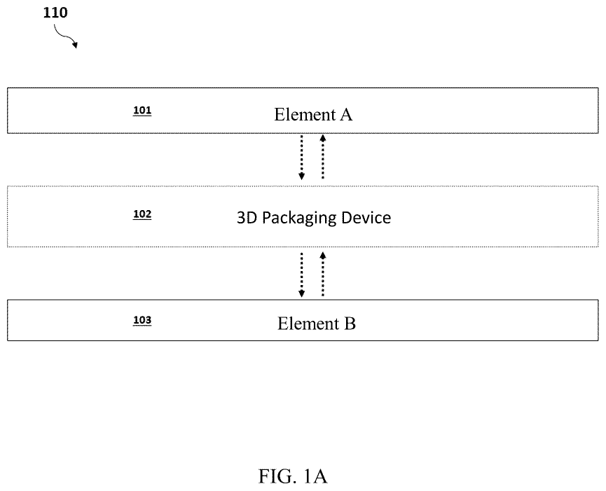

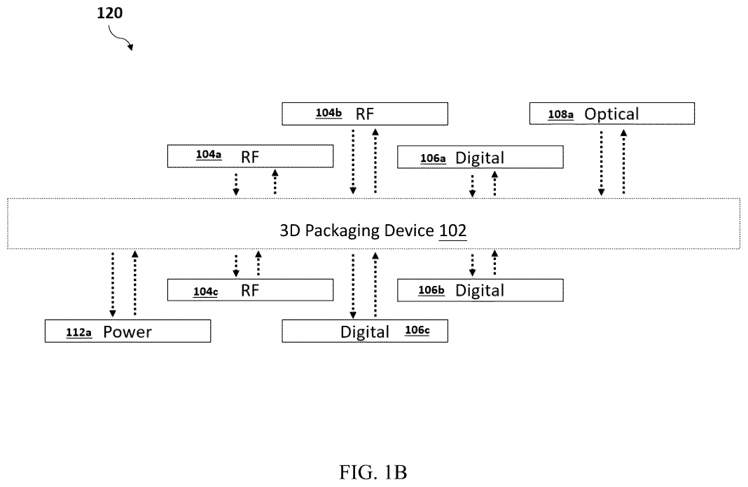

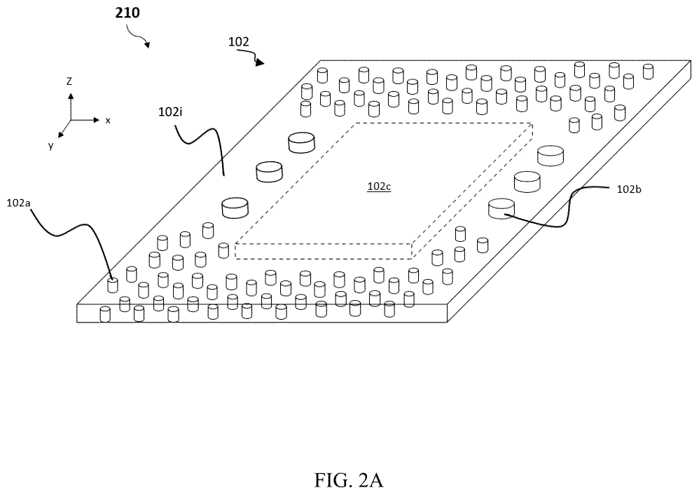

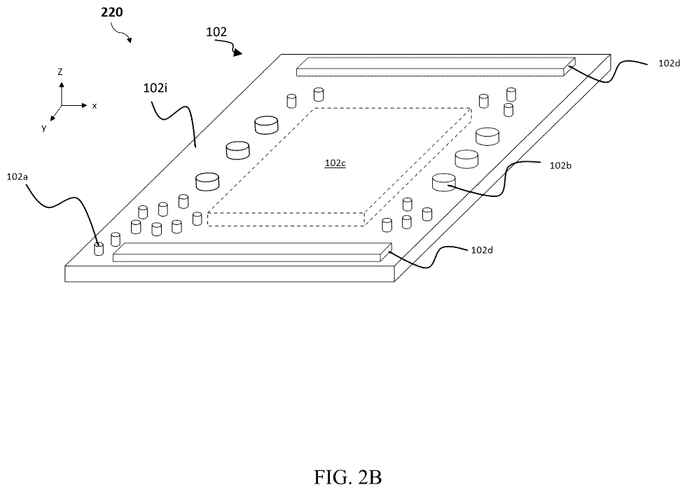

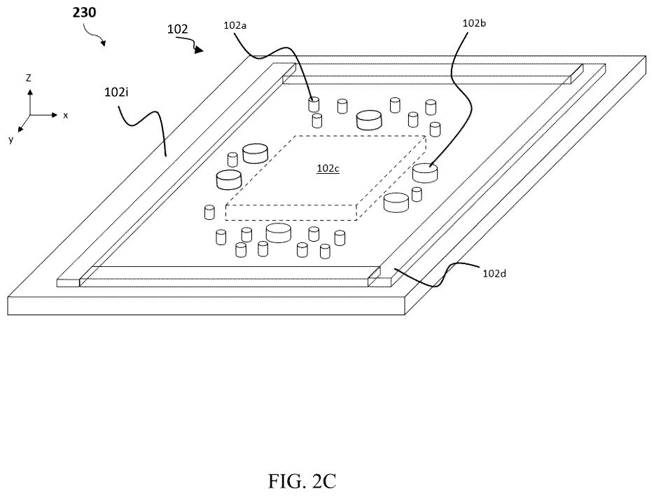

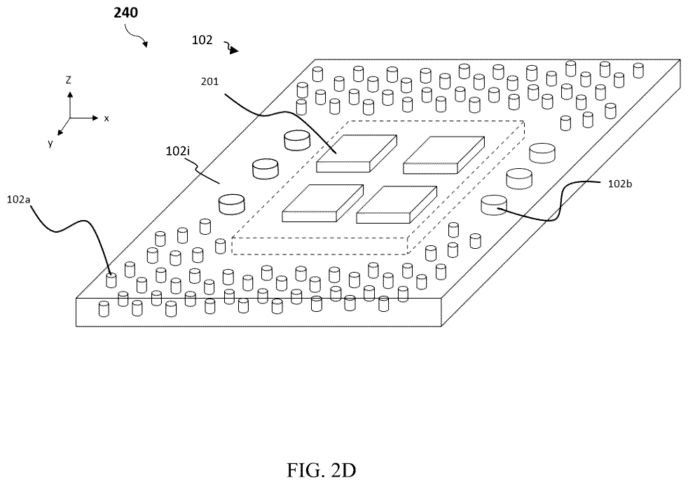

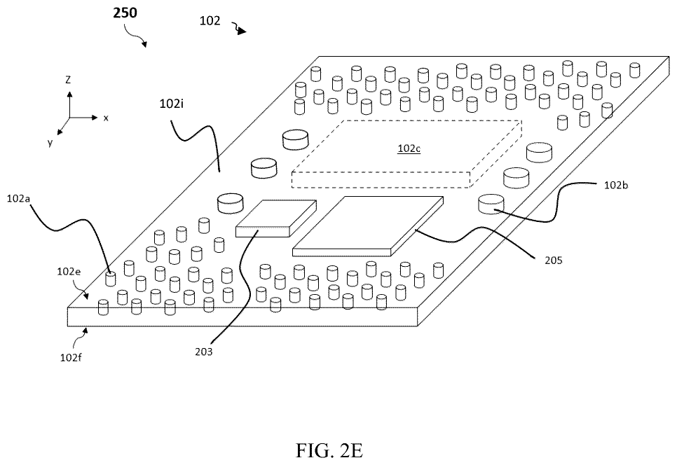

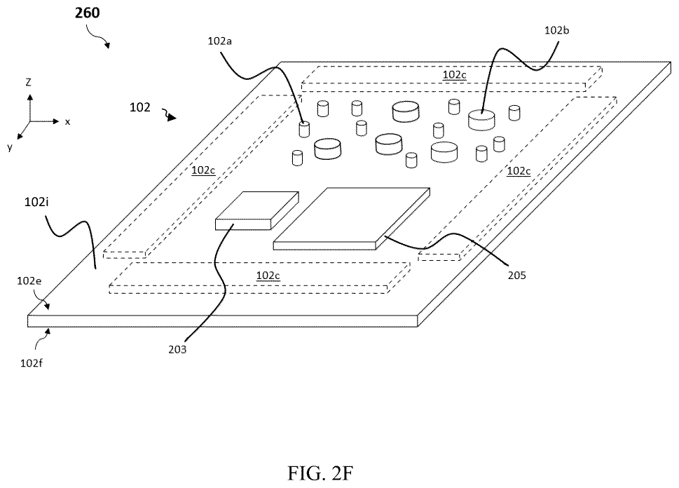

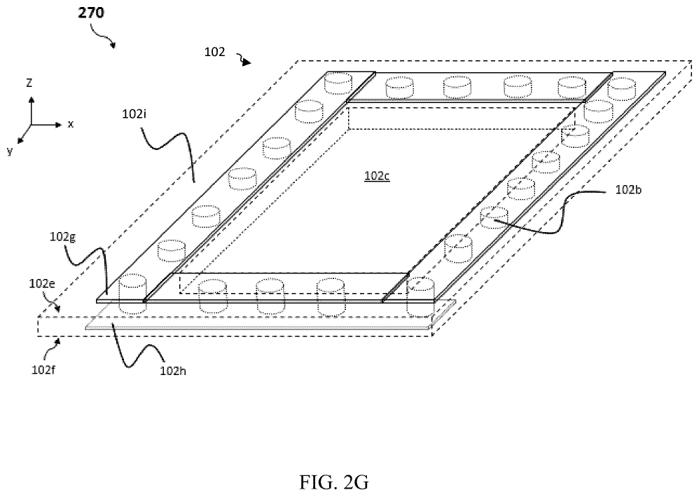

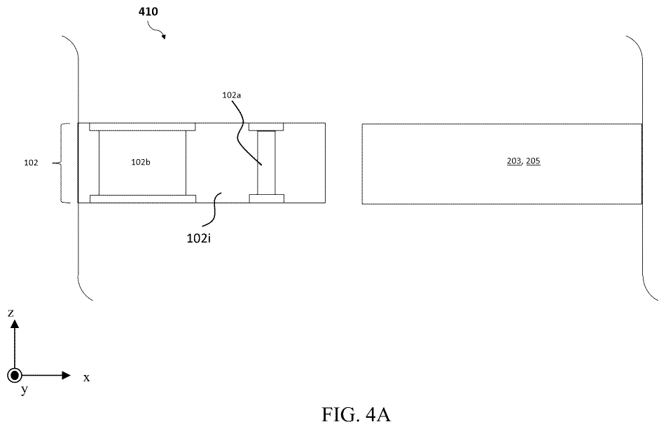

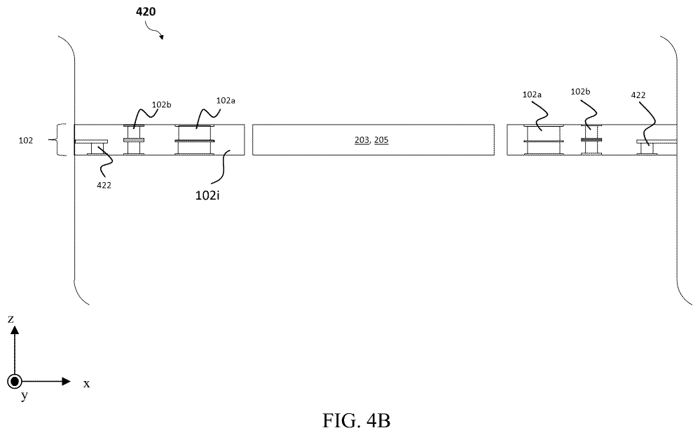

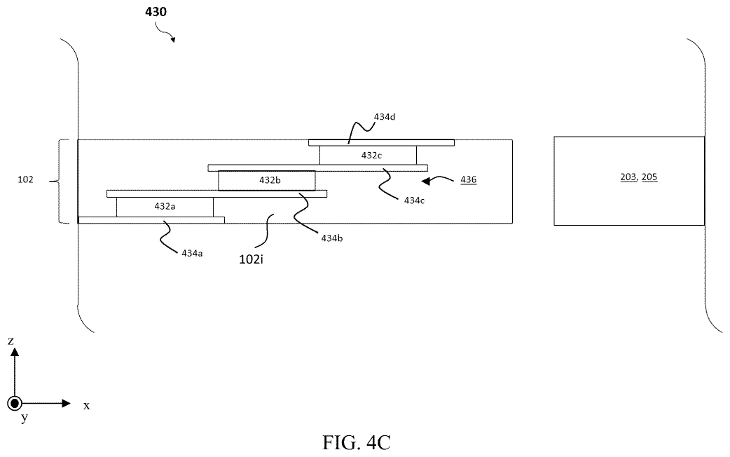

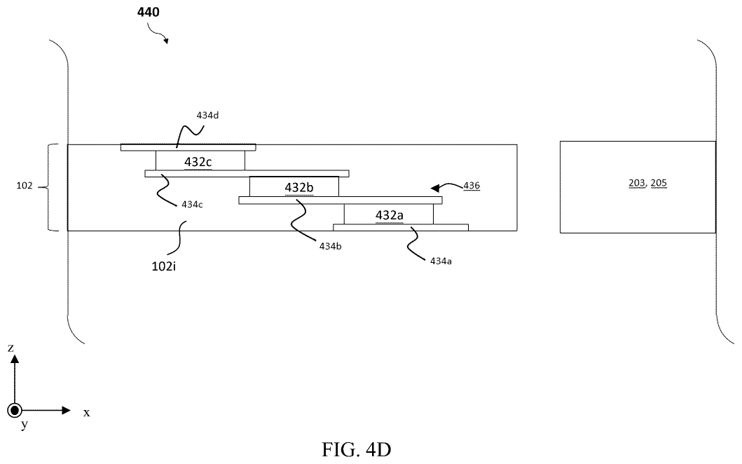

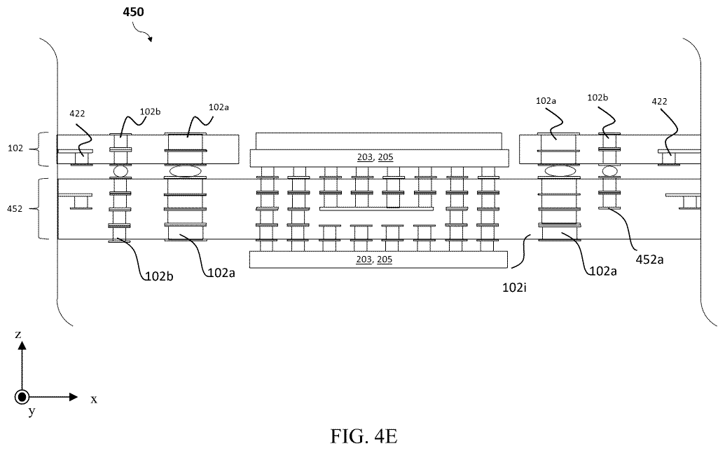

FIG. 1A illustrates a systems 110 that a 3D packaging device 102 is coupled with elements A and B (101 and 103) in the z-direction (e.g., vertical direction), according to embodiments of the present disclosure. Element A 101 and element B 103 may be simultaneously coupled to the same side/surface of 3D packaging device 102, or may be respectively coupled to a different side/surface of 3D packaging device 102. 3D packaging device 102 may include an interposer substrate (e.g., an interposer substrate) and a plurality of connection structures in the interposer substrate. The interposer substrate may include a composite of metal and laminate. For example, the interposer substrate may include one or more layers of metal, fabric, paper, plastic, resin, etc. In some embodiments, the metal in interposer substrate may include copper (Cu), aluminum (Al), aluminum copper (AlCu), silver (Ag), gold (Au), tin (Sn), etc. The connection structures may include vias for transmitting electrical signals, channels for conveying cooling fluids, optical fibers for transmitting optical signals, heat spreaders for conducting heat, etc. In some embodiments, the vias include a suitable metal such as Cu, Al, AlCu, Ag, Au, Sn, or any combination. In some embodiments the channels include a suitable metal such as Cu, Al, AlCu, Ag, Au, Sn, or any combination, or other suitable materials such as polymer, plastic, glass, ceramic, or any suitable media that is configured to allow for fluidic or other cooling materials to permeate through the 3D packaging device. The structures and materials of the connection structure are described in FIGS. 2A-2G, and 4A-4E. Elements A and/or B (101 and/or 103) may be coupled to 3D packaging device 102 through a bonding process (e.g., hybrid bonding, metal-to-metal bonding, etc.), a soldering process, an adhesion process, or so. Signals and/or heat in element A 101 may be conveyed to element B 103 through the connection structures of 3D packaging device, and vice versa. In various embodiments, element A 101 and element B 103 may include other 3D packaging devices and/or dies.

In some embodiments, elements A 101 and elements B 103 may be heterogeneous elements. Elements 101 and 103 may include microelectronic die comprised of silicon (Si), gallium nitride (GaN), gallium arsenide (GaAs), indium phosphide (InP), and other materials. Elements 101 and 103 may also include interposers and/or substrates comprising laminate metal composites, glass/metal composites, and/or metal/air composites. In some embodiments, element A 101 and element B 103 may communicate RF and/or digital signals through the 3D packaging device 102 and/or process RF, optical, and/or digital signals directly to each other. In some embodiments, element A 101 and/or element B 103 are cooled by 3D packaging device 102, and may or may not communicate with each other. In various embodiments, 3D packaging device 102 is different from an interposer or a laminate. For example, 3D packaging device 102 may include connection structures in RF, optical, mechanical, and thermal, in addition to electrical (which is typically the only. (which is typically the only type of connection structures in an interposer or a laminate.

FIG. 1B illustrates a 3D structure 120 having a 3D packaging device 102 coupled to various different dies on each side/surface in the z-direction (e.g., vertical direction), according to some embodiments. For example, 3D packaging device 102 may be configured to couple dies/elements that are configured for different functions. For example, a RF element/die may generate/transmit a RF signal and/or an electrical signal, a digital element/die may generate/transmit an electrical signal, an optical element/die may generate/transmit an optical signal, a power element/die may generate/transmit an electrical signal. In some embodiments, system 120 having 3D packaging device 102 interconnecting disparate heterogeneous RF elements/dies 104a-c, digital elements/dies 106a-c, power element/die 112a, and optical element 108a. 3D packaging device 102 may enable electrical, RF, thermal, and optical interconnectivity of the element(s) 104a-c, 106a-c, 108a, and/or 112a. 3D packaging device 102 may enable each element to interconnect each disparate element regardless of function and material composition. 3D packaging device 102 may provide interconnection in three dimensions and operable to provide electrical, RF, fluid, and optical signal transmission. 3D packaging device 102 also provides cohesion of the element(s) 104a-c, 106a-c, 108a, and 112a for packaging of systems and for managing thermal dissipation. In some embodiments, the RF elements/dies 104a-c may be coupled to 3D packaging device 102 via RF connection structures, which may include copper pillars. Two adjacent copper pillars may have a pitch between about 25 μm and about 50 μm. The copper pillars may be disposed upon one or more surfaces of the RF elements 104a-c and may connect to one or more disparate heterogeneous elements. The copper pillars may include a stand-off height of about 15 μm. In some embodiments, other suitable materials conductive of RF signals, such as solder or conductive epoxy, may also be used in the RF connection structures.

FIGS. 2A-2G show different configurations of a 3D packaging device 102, according to some embodiments. Depending on the application, 3D packaging device 102 may be designed to accommodate various different structures that are coupled to it. For example, the types, number, arrangement, and/or the locations of channel structures can be flexibly customized based on the structure to be coupled to 3D packaging device 102.

FIG. 2A shows a configuration 210 of 3D packaging device 102. 3D packaging device 102 include one or more connection structures 102a, one or more connection structures 102b, and an opening 102c. In some embodiments, connection structures 102a and 102b extend through an interposer substrate 102i of 3D packaging device 102, e.g., extending from the first surface (e.g., top surface) to the second surface (e.g., bottom surface) of interposer substrate 102i, and may have different functions. For example, connection structures 102a and 102b may be employed to convey a respective one of an electrical signal, a RF signal, an optical signal, fluid (e.g., cooling fluid), heat, etc. For example, connection structures 102a and/or 102b may include a metal via for transmitting an electrical signal and/or a RF signal, an optical fiber for transmitting an optical signal, a channel structure for transmitting fluid, a metal heat spreader for transferring heat. In some embodiments, connection structures 102a include signal vias, and connection structures 102b include power vias. 3D packaging device 102 may include one or more interconnect layer(s) having metal layers/traces (not shown) that connect to the respective vias 102a and/or 102b. In an embodiment, 3D packaging device 102 may include a composite of laminate and metal layer(s). In some embodiments, 3D packaging device 102 may include metal layers/traces connecting the vias 102a and/or 102b. The metal traces may be over the surface of 3D packaging device 102 and may be substantially surrounded by air. In some embodiments, the metal traces may be embedded in interposer 102i. In some embodiments, 3D packaging device 102 may also operate as a thermal cooling solution to dissipate heat generated by electronics, RF, Power, and optical elements. For example, at least one of channel structures 102a and 102b include a channel structure for conveying cooling fluids in the z-direction or a metal heat spreader for conducting heat in the z-direction. In some embodiments, channel structures 102a and 102b are arranged in respective matrix.

In some embodiments, opening 102c may include a shallow/recess area on interposer substrate 102i. For example, opening 102c may include a surface located between the top surface and bottom surface of interposer substrate 102i. Opening 102c may have a desirable depth from the surface (e.g., top surface) for a die to be placed in. Although not shown, 3D packaging device 102 may or may not include connection structures (102a and/or 102b) in opening 102c for coupling the die with 3D packaging device 102. In some embodiments, opening 102c is a Faraday cage that wholly surrounds the die, and partially or fully shields the electromagnetic fields around the die.

FIG. 2B shows another configuration 220 of 3D packaging device 102. In some embodiments, different from configuration 210, in configuration 220, 3D packaging device 102 may include one or more thermal elements 102d (e.g., heat sink structures) disposed on a surface (e.g., a top surface) of interposer substrate 102i. In some embodiments, thermal elements 102d may extend along the perimeter of 3D packaging device 102, and may have a stripe shape. In some embodiments, thermal elements 102d may have a thermal conductivity of at least 1 W/(m·K). In some embodiments, thermal elements 102d include metal, such as copper (Cu), aluminum copper (AlCu), aluminum (Al), silver (Al), gold (Au), or a combination. Thermal elements 102d may conduct at from any die/3D packaging device that is in contact with thermal elements 102d. For example, thermal elements 102d may conduct heat from any die/3D packaging device that is coupled to 3D packaging device 102 and in contact with thermal elements 102d. In some embodiments, thermal elements 102d may be coupled to the die (placed in opening 102c) via metal traces/layers or heat spreaders, such that thermal elements 102d can dissipate heat generated from electronics, RF, Power, and/or optical elements by the dies (e.g., in opening 102c).

FIG. 2C shows another configuration 230 of 3D packaging device 102. In some embodiments, different from configuration 220, in configuration 230, thermal elements 102d may be arranged into a frame circumventing the perimeter of 3D packaging device 102. For example, thermal elements 102d may be arranged to connect one another around the perimeter of 3D packaging device 102, forming a frame. In some embodiments, similar to configuration 220, thermal elements 102d may include metal. In this manner, thermal elements 102d, in addition to or as an alternative function of dissipating heat, may provide a means for a hermetic metal seal with another 3D packaging device (not shown) and/or package materials such as a metallized lid.

FIG. 2D shows another configuration 240 of 3D packaging device 102. In some embodiments, different from configuration 210, in configuration 240, one or more dies 201 may be disposed in opening 102c. The dies 201 may be comprised of Si, SiC, GaN, GaAs, and/or other materials. The dies 201 may be disposed on a substrate (not shown) and interconnected to the substrate (not shown) via a suitable connection such as Cu pillars, and/or solder bumps. Optionally or additionally, dies 201 may also be mounted on the substrate (not shown) with conductive material and connected to either 3D packaging device 102 and/or the substrate (not shown) via wire bonds. In some embodiments, dies 201 may be attached to the substrate (not shown) via hybrid bond wherein the substrate (not shown) may include a Si interposer or an advanced substrate having silicon, exposed metal such as Cu, and a dielectric such as benzocyclobutene (BCB), silicon nitride, tetraethyl orthosilicate (TEOS), and/or thermal oxide.

FIG. 2E shows another configuration 250 of 3D packaging device 102. In some embodiments, different from configuration 210, in configuration 250, 3D packaging device 102 may include a die 203 and a die 205 disposed on either the top surface 102e and/or the bottom surface 102f of 3D packaging device 102. In some embodiments, dies 203 and 205 are disposed outside opening 102c. In some embodiments, die 203 and/or 205 may be embedded in 3D packaging device 102, e.g., between top surface 102e and bottom surface 102f, and may be connected to at least ones of the connection structures 102a and/or 102b. Dies 203 and/or 205 may be operable to affect an RF and/or a digital signal. In some embodiments, the 203 and/or 205 may be operable to transmit and/or receive an optical signal via an optical fiber or a fiber bundle (not shown).

FIG. 2F shows another configuration 260 of 3D packaging device 102. In some embodiments, different from configuration 210, in configuration 260, 3D packaging device 102 may include more than one opening 102c. The openings 102c may be configured at multiple location(s) about the 3D packaging device 102. In some embodiments, openings 102c may be configured to extend along the perimeter of 3D packaging device 102, and may be configured to allow for thermal coolant and/or air flow within. For example, openings 102c may be hollow or may be filled with cooling fluids and/or air. In some embodiments, the opening 102c may be configured to allow for feed through or clearance of components, dies, etc., disposed on other interposers in the z-direction with respect to the x-y plane of 3D packaging device 102.

FIG. 2G shows another configuration 270 of 3D packaging device 102. In some embodiments, different from configurations 210-260, in configuration 270, opening 102c may extend from the front surface of interposer substrate 102i to the bottom surface of interposer substrate 102i such that 3D packaging device 102 has a frame shape. In some embodiments, 3D packaging device 102 includes connection structures of the same length in the z-direction. For example, 3D packaging device 102 includes connection structures 102b. In some embodiments, 3D packaging device 102 includes traces/stripes 102g disposed on the topside 102e (e.g., top surface) and traces/tripes 102h on bottom side 102f (e.g., bottom surface) of interposer substrate 102i. The connection structures 102b may connect to the traces 102g and 102h that form a frame or other structure configured for mechanical compliance and/or thermal management of various electrical, optical, and/or thermal loading elements (not shown). In some embodiments, traces 102g and 102h function as the top and bottom surfaces of interposer substrate 102i. In some embodiments, traces 102g and 102h include laminate and/or metal. In some embodiments, traces 102g and 102h are separated by air, e.g., connection structures 102b are surrounded by air.

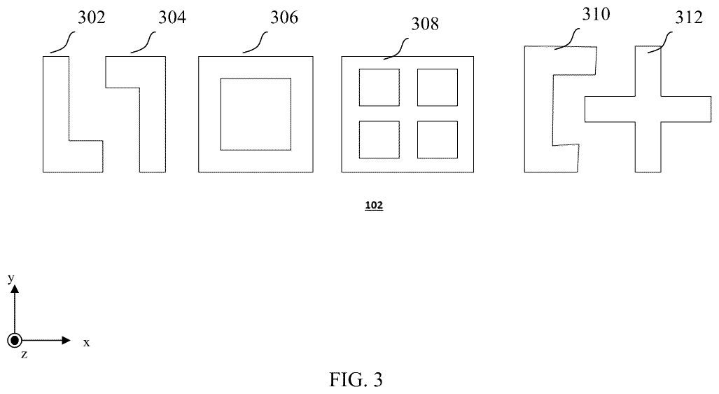

FIG. 3 shows different topographic shapes 302-312 of a 3D packaging device 102, according to some embodiments. In various embodiments, any one or more of the configurations 210-270 may also be applied with any one of the shapes 302-310, according to some embodiments. For example, 3D packaging device 102 may have an “L” shape (e.g., of different ratios and/or orientations, as in 302 and 304), a frame shape (as in 306), a cross-in-frame shape (as in 308), an irregular shape (as in 310), a cross shape (as in 312). In some embodiments, 3D packaging device 102 also includes other shapes such as a triangular shape, a circular shape, a polygon shape, etc.

FIGS. 4A-4E show cross-sectional views of exemplary 3D packaging device 102 in different configurations shown in FIGS. 2A-2G, according to some embodiments. For ease of illustration, dies 203 and 205 are shown as references. In some embodiments, dies 203 and 205 are a RF die and a digital die, respectively. In some embodiments, dies 203 and 205 are embedded in 3D packaging device 102 or placed in opening 102c (referring back to the description of FIGS. 2A-2F).

FIG. 4A shows a scenario 410 in which 3D packaging device 102 includes connection structures 102a and 102b. In some embodiments, connection structures 102a includes an electrical via that extends from the top/first surface of interposer substrate 102i to the bottom/second surface of interposer substrate 102i. For example, connection structures 102a may be electrically coupled to electrical features/traces on both surfaces of interposer substrate 102i. In some embodiments, connection structures 102b includes a heat spreader or a heat sink. Connection structures 102 may transfer heat through interposer substrate 102i, e.g., from its one end to the other end.

FIG. 4B shows a scenario 420 in which 3D packaging device 102 includes connection structures 102a, 102b, and 422. Connection structures 422 may include an electrical via that extends from one surface of interposer substrate 102i into a position between the two surfaces of interposer substrate 102i. In other words, connection structures 422 are partially through interposer substrate 102i. In some embodiments, connection structures 422 are electrically coupled to other electrical features, such as metal traces, and/or routing layers embedded in interposer substrate 102i. As an example, connection structure 422 extends from the bottom surface of interposer substrate 102i into interposer substrate 102i.

FIG. 4C shows a scenario 430 in which 3D packaging device 102 includes a connection structure 436. In some embodiments, connection structure 436 includes an electrical via that extends from one surface to the other surface of interposer substrate 102i. Different from connection structure 102a, connection structure 436 does not extend in the z-direction. Instead, connection structure 436 includes a plurality of sub-vias 432a, 432b, and 432c, each electrically connected one another by a metal trace or a routing layer (e.g., 434b, 434c), cascading away from dies 203 and 205 from the top surface to the bottom surface of interposer substrate 102i. Connection structure 436 may further include contact layers (or metal traces) 434a and 434d in contact with a respective surface of interposer substrate 102i and a respective sub-via. As shown in FIG. 4C, contact layer 434d is in contact with (or disposed on) the top surface of interposer substrate 102i, and is in contact with sub-via 432c, which is further in contact with metal trace 434c. Metal trace 434c is then in contact with sub-via 432b, which is further in contact with metal trace 434b. Metal trace 434b is then in contact with sub-via 432a, which is further in contact with contact layer 434a. Contact layer 434a is in contact with (or disposed on) the bottom surface of interposer substrate 102i. In some embodiment, metal traces 434a, 434b, and 434c also function as heat spreaders or heat sinks. In various embodiments, the vertical projections of sub-vias 432a, 432b, and 432c may or may not overlap with one another in the x-y plane, depending on the design. In some embodiments, connection structure 436 includes a suitable conductive material such as metals including, Cu, Al, AlCu, Ag, Au, or a combination.

FIG. 4D shows a scenario 440 in which 3D packaging device 102 includes a connection structure 436 that has a cascading structure towards dies 203 and 205 from the top surface to the bottom surface of interposer substrate 102i. Detailed description of connection structure 436 in scenario 440 may be referred to that of scenario 430, and is not repeated herein.

FIG. 4E shows a scenario 450 in which 3D packaging device 102 is coupled with another 3D packaging device 452. As shown in FIG. 4E, dies 203 and 205 may be coupled to both the top surface and the bottom surface of 3D packaging device 102, through suitable coupling and/or bonding means, such as hybrid bonding, soldering, adhesion, or a combination. Connection structures 102a of 3D packaging devices 102 and 452 may be coupled through a soldering structure that includes Sn (e.g., a soldering bump). Connection structures 102b of 3D packaging devices 102 and 452 may be coupled through suitable thermally-conductive metal such as Sn and/or Cu. In some embodiments, connection structures 102b may be coupled to connection structures 452a, which may be similar to connection structure 102b but does not extend through 3D packaging device 452. Although not shown, in some embodiments, connection structure 102a is coupled with connection structure 422 through a soldering structure.

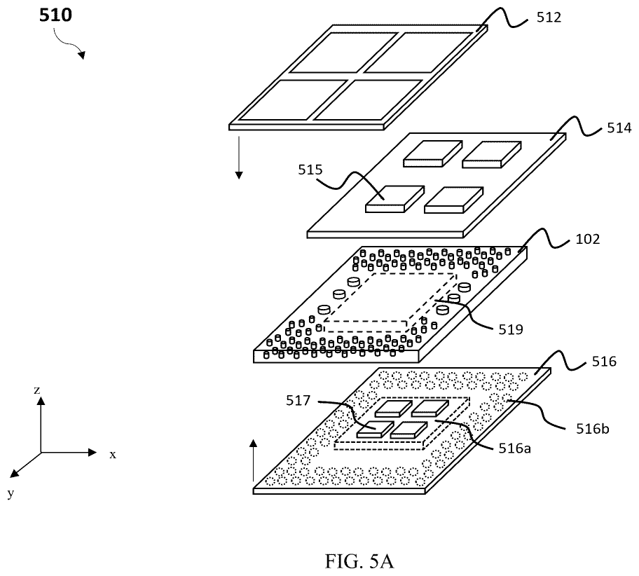

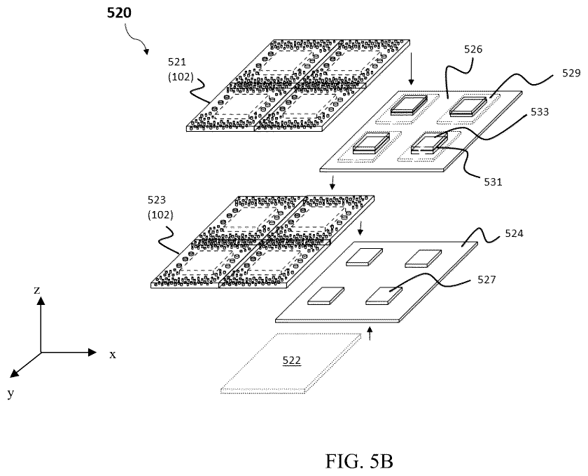

One or more 3D packaging devices may be integrated in a 3D structure of various functionalities, such as electrical, RF, optical, etc. Each 3D packaging device may be employed to couple one or more structures vertically (in the z-direction). FIG. 5A illustrates an exploded view of a 3D structure 510 that includes a 3D packaging device 102 coupled with interposers 512, 514, and 516. As an example, 3D packaging device 102 may be coupled with interposers 512 and 514 on the top surface, and interposer 516 on the bottom surface. In various embodiments, the coupling may include digital, thermal, optical, or any combination. In some embodiments, 3D packaging device 102 is in contact with the interposer 516 and bonded to the respective connection structures 516b for digital, RF, thermal, and/or optical connections. In some embodiments, connection structures 516b may include any of the aforementioned channel structures 112a, 112b, 422, 436, 452a, etc. In some embodiments, 3D packaging device 102 is coupled to interposers 514 and to interposer 512. In some embodiments, one or more dies 516a are coupled to the bottom surface of interposer 102 and coupled to dies 517 and/or 519 through interposer 516.

In some embodiments, one or more die 517 may be embedded in interposer 516. In some other embodiments, die 517 may be disposed on one or both of the opposing sides of the interposer 516. The interposer 516 may comprise one or more digital, RF, and/or power management micro-devices, and may include semiconductor materials such as Si, GaN, GaAs, and InP. In some embodiment, die 517 may include a Si die operable as a beamformer or may include a transceiver operable to convert RF signals to digital signals and/or digital signals to RF signals.

Interposer 514 may include one or more die 515 embedded and/or disposed on one or both of the opposing sides. Die 515 may include micro-devices configured for RF linear noise amplification (LNA) and/or other power amplification (PA). In some embodiments, die 515 may include two or more heterogeneous dies stacked upon respective opposing circuit planes. The heterogeneous dies may include, for example, a GaAs LN stacked thereupon a GaN PA micro-device. In some embodiments, the heterogeneous dies are coupled to 3D packaging device 102 through Cu pillars and/or solder bumps. In some embodiments, the heterogeneous dies are coupled to 3D packaging device 102 through direct contact, such as via grown Cu damascene interconnect, and/or bonded via Cu/oxide hybrid fusion bond.

In some embodiments, one or more dies 519 are coupled to the bottom surface of interposer 102 and coupled to dies 517 through interposer 102.

Disposed over the interposer 514 and die 515 is the interposer 512, in an embodiment, may be configured with one or more antenna structure(s) (not shown) that are interconnected to the interposer 512, 514, 516, and the Z-fabric 102.

FIG. 5B illustrates an exploded view of a 3D structure 520 that includes 3D packaging devices 521 and 523 coupled to interposers 524 and 526. 3D packaging devices 521 and 523 may each be an example of 3D packaging device 102. In some embodiments, 3D packaging device 523 is in contact with interposer 524 and bonded to respective connection structures (not shown) which may include one or more of digital, RF, thermal, and/or optical connection structures, e.g., including any of the aforementioned channel structures 112a, 112b, 422, 436, 452a, etc. In some embodiments, 3D packaging device 523 is also bonded to interposer 526. In some embodiments, 3D packaging device 521 is coupled to interposer 526.

Interposer 524 may include one or more dies 527 embedded and/or disposed on at least one of the opposing sides. Dies 527 may include micro-devices configured for up/down conversion and/or may include RF linear noise amplification (LNA) and/or other power amplification (PA).

In some embodiments, dies 533 and 531 may include heterogeneous dies stacked upon respective opposing circuit planes in the z-direction. Dies 531 and 533 may include, for example, a GaAs LN stacked thereupon a GaN PA micro-device. In some embodiments, dies 531 and 533 might include Cu pillars and/or solder bumps. In some embodiments, dies 531 and 533 may be in direct contact with 3D packaging device 521 via grown Cu damascene interconnect and/or bonded via Cu/oxide hybrid fusion bond.

In some embodiments, one or more dies 529 (e.g., bean-forming dies) are coupled to the bottom surface of interposer 526 and coupled to dies 531 and/or 533 through interposer 526. In some embodiments, dies 529 are coupled to dies 531 and/or 533 through 3D packaging device 521 and/or 523.

In some embodiments, one or more dies 522 (e.g., digital/RF transceiver die 522) are coupled to the bottom surface of interposer 524. Die(s) 522 may be connected to die 527 through interposer 524. In some embodiments, die(s) 522 are coupled to die 527 through 3D packaging devices 521 and 523.

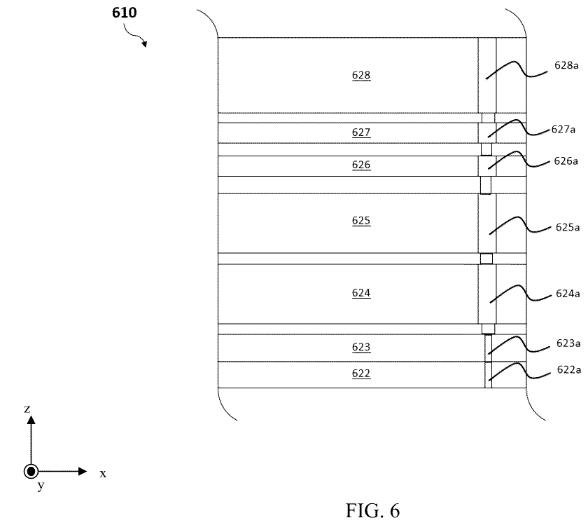

FIG. 6 shows the coupling between 3D packaging devices, between a 3D packaging device and an interposer, between a 3D packaging device and a die, etc. FIG. 6 shows the cross-sectional view of a 3D structure 610 (e.g., a heterogeneously stacked structure) may include one or more 3D packaging devices. In some embodiments, 3D structure 610 may be operable for processing of RF frequency ranges about the Ka-band frequency range (e.g., 26.5-40 gigahertz (GHz)). In some embodiments, 3D structure 610 includes a digital processing die 622 and a RF transceiving/digital filtering 623 stacked along the z-direction. A 3D packaging device 624 may be disposed on die 623, and a 3D packaging device 625 may be disposed on 3D packaging device 624. 3D packaging devices 624 and 625 may be configured for power and thermal management and may include various traces and vias for transmitting digital, RF, and optical signals. In some embodiments, 3D packaging devices 624 and 625 may include fluid channels that are coupled in the z-direction. In some embodiments, the fluid channels may help the dissipation of thermal energy from die 626, 627 and an interposer 628. In some embodiments, interposer 628 may include an array of antenna elements (not shown). In some embodiments, dies 626 and 627 may include a PA and/or LNA function, and in other embodiments might include an RF filter function and/or an optical transceiving function. In some embodiments, the dies 626 and 627 may include copper pillars. In some embodiments, two adjacent copper pillars include a pitch between about 25 μm and about 50 μm. The copper pillars may be disposed upon one or more surfaces of the dies 626 and 627 and may connect to one or more disparate heterogeneous elements. The copper pillars may include a stand-off height of about 15 μm respectfully. The die 626 may be coupled to the 3D packaging devices 624 by the copper pillars that are configured for electrical and thermal conductance.

As shown in FIG. 6A, elements 622-628 are coupled in the z-direction by connection structures 622a, 623a, 624a, 625a, 626a, 627a, and 628a, respectively. The connection structures 622a-628a may include various kinds of connections such as electrical, RF, optical, thermal, etc. In some embodiments, if the two directly coupled channel structures (e.g., 622a and 623a) are electrical vias, the two channel structures are coupled by a suitable soldering structure such as Sn. In some embodiments, if the two directly coupled channel structures are fluid channels, they are connected by a micro-channel structure that includes a suitable material such as metal, plastic, or polymer. In some embodiments, if the two directly coupled channel structures are optical fibers, they are connected by epoxy. In some embodiments, if the two directly coupled channel structures are heat spreaders, they may be coupled by thermally conductive epoxy, soldering materials, sinterable materials, and/or suitable thermal interface materials (TIMs).

In some embodiments, 3D structure 610 may be operable for processing of RF frequency ranges about the W-band frequency range. In some embodiment, element 623 is a data converter die, and is coupled with digital processing die 622 on opposing sides. Like the cross section 610, dies 627 and 628 may be disposed upon die 623.

In various embodiments of the present disclosure, the exemplary 3D packaging devices (e.g., 102, 302-312, 452, 521, 523, 624, 625, etc.) may not include a device layer (e.g., the front-end of the line or FEOL layer) that includes an active part of a chip, such as a transistor, a resistor, a capacitor, embedded within. For example, the 3D packaging devices may include only an interposer substrate and any suitable connection structures. Dies may be bonded to the 3D packaging devices. In some embodiments of the present disclosure, a die with active parts of a chip (e.g., a FEOL layer) may be embedded in a 3D packaging device, e.g., between the top and bottom surface of the 3D packaging device. However, the 3D packaging device may not include a back-end of the line (BEOL) layer coupled to (or in contact with) any FEOL layer of the die. For example, a die may include a FEOL layer and a BEOL layer over the FEOL layer, and connection structures of the 3D packaging device may be coupled to the FEOL layer of the die via various suitable couplings. In some embodiments, the FEOL layer of the die and the connection structures of the 3D packaging device are formed separately.

Those skilled in the art will recognize improvements and modifications to the preferred embodiments of the present disclosure. All such improvements and modifications are considered within the scope of the concepts disclosed herein and the claims that follow.

1. A three-dimensional (3D) packaging device, comprising:
an interposer substrate; and
a plurality of connection structures in the interposer substrate, wherein the plurality of connection structures are configured to transmit at least one of an electrical signal, heat, fluid, or an optical signal.

2. The 3D packaging device of claim 1, wherein the plurality of connection structures comprise a first via structure extending from a first surface of the interposer substrate to a second surface of the interposer substrate for transmitting a respective electrical signal.

3. The 3D packaging device of claim 2, wherein the first via structure comprises a metal via.

4. The 3D packaging device of claim 2, wherein the first via structure comprises a plurality of sub-vias cascaded from the first surface of the interposer substrate to the second surface of the interposer substrate, each of the sub-vias being electrically coupled to another one of the sub-vias with a metal layer.

5. The 3D packaging device of claim 2, wherein the first surface of the interposer substrate comprises a first metal layer and the second surface of the interposer substrate comprises a second metal layer, the first metal layer and the second metal layer being separated by air.

6. The 3D packaging device of claim 1, wherein the plurality of connection structures comprise a second via structure extending from between a first surface of the interposer substrate and a second surface of the interposer substrate to one of the first surface or the second surface, the second via structure being configured to transmit a respective electrical signal.

7. The 3D packaging device of claim 6, wherein the second via structure comprises:
another metal layer extending from between the first surface of the interposer substrate and the second surface of the interposer substrate to the one of the first surface or the second surface, and
a metal layer between the first surface of the interposer substrate and the second surface of the interposer substrate, and in contact with the other metal layer.

8. The 3D packaging device of claim 1, wherein the plurality of connection structures comprise a heat spreader structure extending a first surface of the interposer substrate to a second surface of the interposer substrate for transferring the heat flow.

9. The 3D packaging device of claim 8, wherein the heat spreader structure comprises a material with a thermal conductivity of equal to or greater than 1 W/(m·K).

10. The 3D packaging device of claim 1, wherein the plurality of connection structures comprises a channel structure extending from a first surface of the interposer substrate to a second surface of the interposer substrate for transmitting the fluid.

11. The 3D packaging device of claim 10, wherein the channel structure comprises mechanisms for fluidic transport.

12. The 3D packaging device of claim 1, wherein the plurality of connection structures comprises an optical fiber for transmitting the optical signal.

13. The 3D packaging device of claim 1, wherein the interposer substrate comprises one or more layers of metal, fabric, paper, plastic, or resin.

14. The 3D packaging device of claim 1, further comprising a heat sink structure on a perimeter of a first surface or a second surface of the interposer substrate, wherein the heat sink structure comprising a metal.

15. The 3D packaging device of claim 14, wherein the heat sink structure forms a frame that circumventing a perimeter of the interposer substrate.

16. The 3D packaging device of claim 1, wherein the interposer substrate comprises an opening, the opening having a surface disposed between a first surface and a second surface of the interposer substrate.

17. The 3D packaging device of claim 16, further comprising a die disposed in the opening.

18. The 3D packaging device of claim 1, further comprising a plurality of openings arranged on a perimeter of the interposer substrate, the openings configured to be filled with fluid or air.

19. The 3D packaging device of claim 1, further comprising a plurality of dies disposed on a first surface of the interposer substrate or a second surface of the interposer substrate through the plurality of connection structures.

20. The 3D packaging device of claim 19, wherein the plurality of dies comprises at least a beamformer device, a radio frequency (RF) transceiver, RF linear noise amplification (LNA) device, a power amplifier (PA) device, or a stacked heterogeneous device of LNA and PA.
